(19) United States
(12) Patent Application Publication
(10) Pub. No.: US 2007/0231601 A1
(43) Pub. Date: Oct. 4, 2007

(54) ORGANIC ELECTROLUMINESCENT DEVICE AND DISPLAY APPARATUS

(75) Inventors: Minako Nakasu, Tokyo (JP); Satoshi Igawa, Fujisawa-shi (JP); Jun Kamatani, Tokyo (JP); Ryota Ooishi, Yokohama-shi (JP); Takao Takiguchi, Tokyo (JP); Shinjiro Okada, Kamakura-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 11/690,166

(22) Filed: Mar. 23, 2007

(30) Foreign Application Priority Data
Mar. 28, 2006 (JP) 2006-087017
Feb. 6, 2007 (JP) 2007-026680

(51) Int. Cl. H01L 51/54

(52) U.S. Cl. 428/690; 428/917; 428/212; 313/504; 313/506; 257/E51.044

(57) ABSTRACT

An organic electroluminescent device includes an anode, a cathode, a luminescent layer disposed between the anode and the cathode, and a hole-transporting layer disposed between the anode and the cathode. The luminescent layer includes a first sublayer made of a first metal complex and a second sublayer made of a second metal complex. The second sublayer is disposed further from the hole-transporting layer than the first sublayer.

### BACKGROUND OF THE INVENTION

1. Field of the Invention

The present invention relates to an organic electroluminescent device (hereinafter also referred to as organic EL device) including an anode, a cathode, and a luminescent layer that is made of an organic compound and that is disposed between the anode and the cathode.

2. Description of the Related Art

Studies of organic EL devices have been actively conducted. A known organic compound constituting a luminescent layer is a metal complex such as tris(2-phenylpyridine) iridium (Ir(ppy)₃) (see Japanese Patent Laid-Open No. 2004-031211). This organic compound is phosphorescent, and organic EL devices that emit phosphorescence have been developed. However, even when the metal complex described in Japanese Patent Laid-Open No. 2004-031211 is used, there is room for further improvement in realizing low-voltage driving and a longer lifetime.

### SUMMARY OF THE INVENTION

The present invention provides a novel organic EL device that provides low-voltage driving and a long lifetime using a metal complex.

The present invention provides an organic electroluminescent device including an anode; a cathode; a luminescent layer disposed between the anode and the cathode; and a hole-transporting layer disposed between the anode and the cathode, wherein the luminescent layer includes a first sublayer comprising a first metal complex and a second sublayer comprising a second metal complex which is disposed further from the hole-transporting layer than the first sublayer.

According to the organic EL device of the present invention, the luminescent layer is composed of a plurality of sublayers, and each of the sublayers is made of a different metal complex. As a result, low-voltage driving and a long lifetime can be realized compared with an organic EL device including a luminescent layer composed of a single sublayer made of a metal complex.

Further features of the present invention will become apparent from the following description of exemplary embodiments with reference to the attached drawings.

### BRIEF DESCRIPTION OF THE DRAWINGS

FIG. 1 is a schematic view showing a stacked state of an organic EL device of Example 1.

FIG. 2 is a graph including an emission spectrum of the organic EL device of Example 1 compared to Comparative Examples 1 and 2.

FIG. 3 is a graph including an emission spectrum of an organic EL device of Example 2 compared to Comparative Examples 3 and 4.

### DESCRIPTION OF THE EMBODIMENTS

An organic electroluminescent device according to an embodiment of the present invention includes an anode, a cathode, and a luminescent layer disposed between the anode and the cathode.

In addition to the luminescent layer, the organic electroluminescent device further includes a hole-transporting layer provided between the anode and the cathode. The luminescent layer is composed of a first sublayer made of a first metal complex and a second sublayer that is made of a second metal complex and that is disposed further from the hole-transporting layer than the first sublayer.

As a result, low-voltage driving and a long lifetime can be realized compared with an organic EL device including a luminescent layer composed of a single sublayer made of a metal complex.

It is believed that, according to the inventive structure, recombination of an electron and a hole is not concentrated on the interface between the luminescent layer and the hole-transporting layer, but, instead, is concentrated on interfaces formed between the luminescent sublayers, thereby preventing optical quenching.

In particular, the following relationships may be satisfied. In the relationships, Ip(EML1) represents the ionization potential of the first metal complex, Ea(EML1) represents the electron affinity of the first metal complex, Ip(EML2) represents the ionization potential of the second metal complex, and Ea(EML2) represents the electron affinity of the second metal complex.

Ip(EML1)<Ip(EML2) (1)

Ea(EML1)<Ea(EML2) (2)

In the organic EL device according to this embodiment, both the first sublayer made of the first metal complex and the second sublayer made of the second metal complex, emit light. The colors of light emitted from the sublayers may be different, similar or be different hues of the same color. In order to decrease color misregistration, metal complexes in which the difference in the maximum emission wavelength is 30 nm or less can be used for the sublayers.

The present invention also provides a display apparatus including the organic EL device of the above embodiment as a display element in a display unit and a control circuit for controlling the display of the display unit. In this case, the organic EL device can be used as a pixel of the display unit. The control circuit is, for example, a circuit for controlling emission and non-emission of the organic EL device. More specifically, an example of the control circuit is a switching element such as a TFT. Alternatively, the control circuit may be a component for controlling a switching circuit. More specifically, an example of the control circuit is a shift register.

In addition, the organic EL device of the present invention can be used as an exposure light source of an electrophotographic image-forming apparatus.

In the organic EL device of the present invention, the term “metal complex” means a metal complex that is, inter alia, phosphorescent. The metal complex includes a central metal and coordinated ligand(s). More specifically, examples thereof include metal complexes containing Ir, Pt, Re, Os, Pd, or Rh as the central metal.

Ligands constituting the metal complex may be the same or different. At least one of the ligands can contain a halogen group such as fluorine (F). This is because not only the ionization potential but also the electron affinity of the metal complex is increased by introducing the halogen group in the ligands. At least one of the first metal complex and the second metal complex may have a ligand having a halogen group. The metal complex of the luminescent sublayer adjacent to an electron-transporting layer; that is, the metal complex of the luminescent sublayer made of the second metal complex, can have at least a ligand having a halogen group.

Examples of structural formulae of the metal complexes in the organic EL device according to this embodiment are shown below.

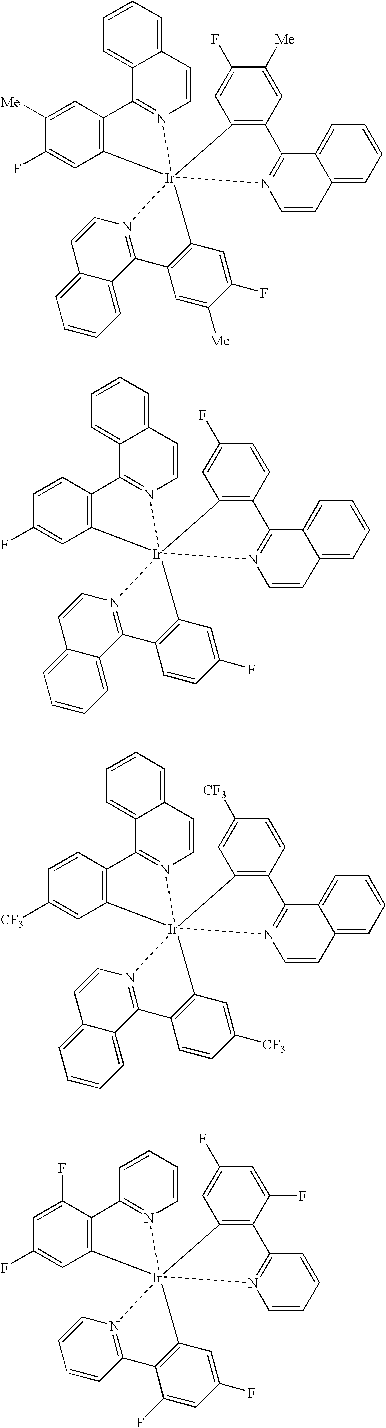

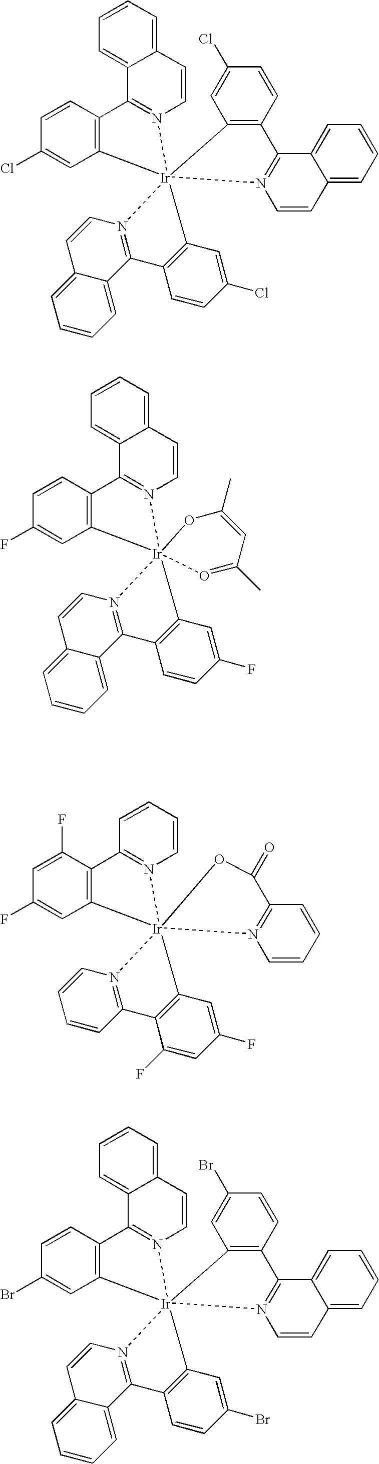

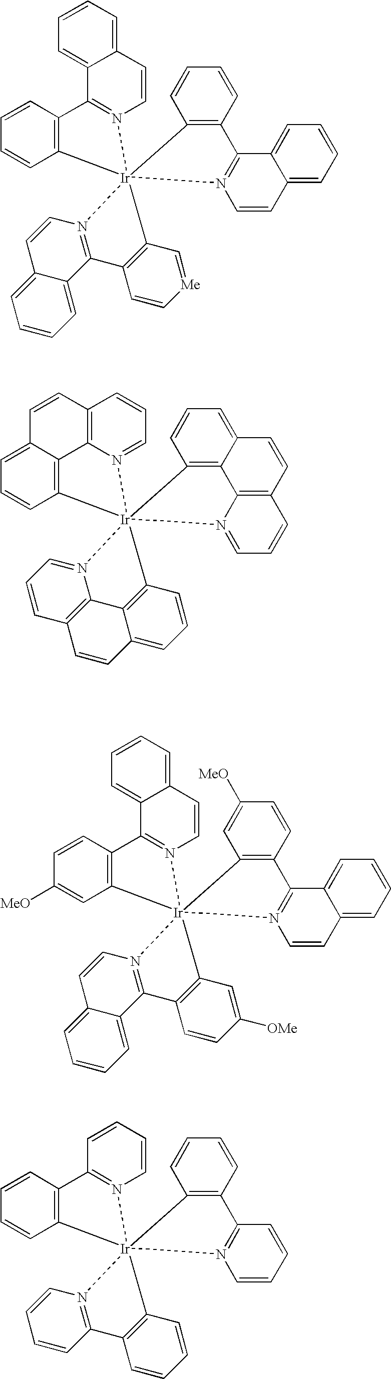

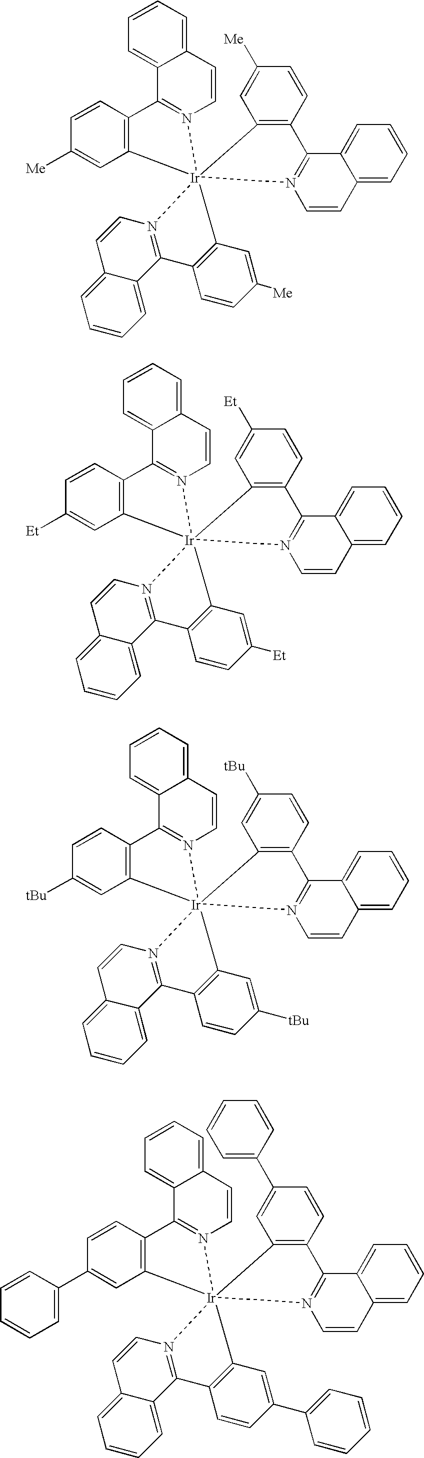

The organic EL device of the present invention includes two luminescent sublayers and a hole-transporting layer. In addition to these layers, various conventionally employed layers may be provided between the anode and the cathode. Examples of the layers include a hole injection layer, an electron-blocking layer, a hole-blocking layer, an electron-transporting layer, and an electron injection layer. These layers may be provided between the anode and the cathode, as needed.

The luminescent layer may further include at least one additional luminescent sublayer. The other luminescent sublayer is not necessarily made of a single metal complex.

### EXAMPLES

### Example 1

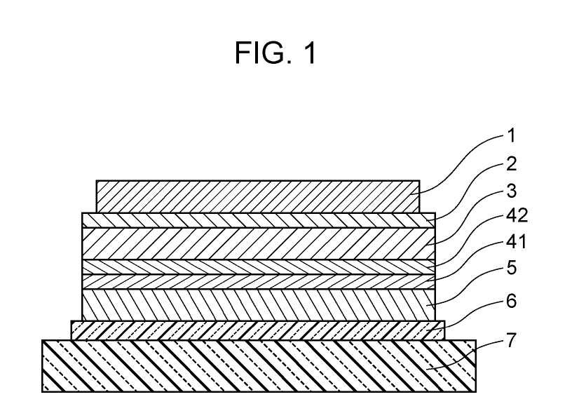

An organic EL device shown in FIG. 1 was prepared. The organic EL device includes a metal electrode 1 serving as a cathode, an electron injection layer 2, an electron-transporting layer 3, a second luminescent sublayer 42, a first luminescent sublayer 41, a hole-transporting layer 5, and a transparent electrode 6 serving as an anode. The first luminescent sublayer 41 is made of a first metal complex. The second luminescent sublayer 42 is made of a second metal complex and disposed further from the hole-transporting layer 5 than the first luminescent sublayer 41. The organic EL device is disposed on a transparent substrate 7.

The indium tin oxide (ITO) film (transparent electrode 6) having a resistance of 11 Ω/sq and a thickness of 120 nm was patterned on the glass substrate (transparent substrate 7) so that a counter electrode area was 3 mm². The ITO substrate was washed with acetone for 10 minutes, isopropyl alcohol (IPA) for 10 minutes, and pure water for 10 minutes while ultrasonic waves were applied in each of the liquids and was then dried at 120° C. for one hour. The ITO substrate was irradiated with UV/ozone for 10 minutes prior to a vacuum deposition. The organic layers and the electrode layer described below were then continuously deposited by resistance heating in a vacuum chamber with a degree of vacuum of 10⁻⁵ Pa. Compounds 1, 2, A, and B are provided hereafter in structural form.

Hole-transporting layer 5 was formed of Compound 1 at a thickness of 20 nm. First luminescent sublayer 41 was formed of first metal complex (Compound B) at a thickness of 5 nm. Second luminescent sublayer 42 was formed of second metal complex (Compound A) at a thickness of 5 nm. Electron-transporting layer 3 was formed of Compound 2 at a thickness of 40 nm. Electron injection layer 2 was formed of LiF at a thickness of 0.5 nm, and metal electrode 1 was formed of Al at a thickness of 120 nm.

In Example 1, Compound B, in which the number of hole carriers was expected to be increased compared with the number of electron carriers, was used as the first luminescent sublayer 41 adjacent to the interface with the hole-transporting layer 5. Similarly, Compound A, in which the number of electron carriers was expected to be increased compared with the number of hole carriers, was used as the second luminescent sublayer 42. Accordingly, a heterostructure entirely composed of a phosphorescent metal complex was formed in the luminescent layer.

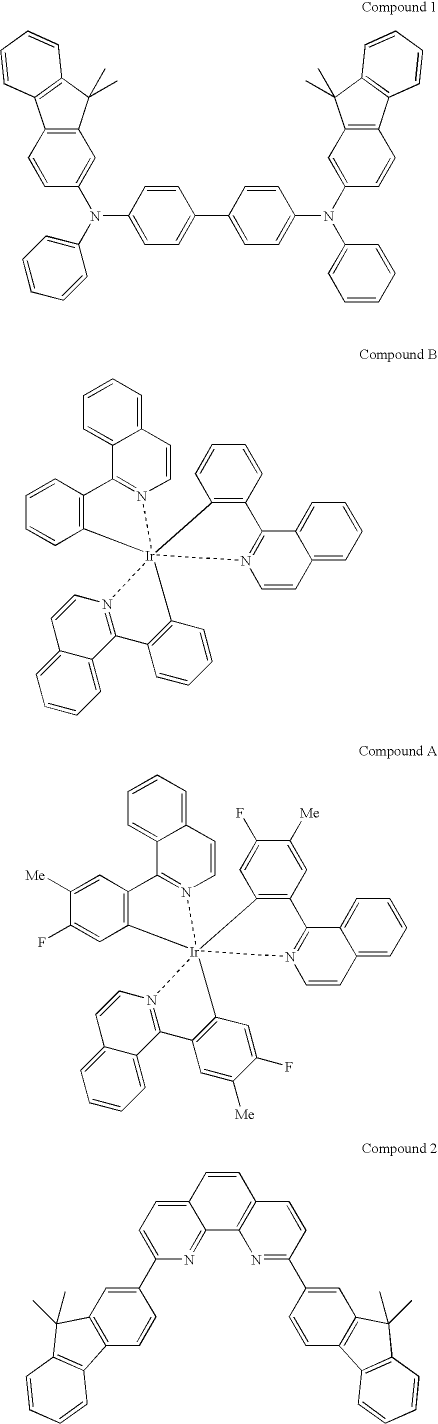

### Comparative Examples 1 and 2

A luminescent layer 4 was composed of a single layer having a thickness of 10 nm. In Comparative Example 1, an organic EL device was prepared as in Example 1 except that the luminescent layer 4 was made of Compound B. In Comparative Example 2, an organic EL device was prepared as in Example 1 except that the luminescent layer 4 was made of Compound A.

Device characteristics of these devices are shown in Table 1. In Table 1, the term “current density” represents a current density (mA/cm²) when the devices are driven at 8 V. The terms “current efficiency” and “power efficiency” in Table 1 represent efficiencies when the luminance reaches 300 cd/m². The term “voltage” in Table 1 represents a voltage when the luminance reaches 300 cd/m². The term “CIE chromaticity” in Table 1 represents a chromaticity when the luminance reaches 300 cd/m². The term “luminance half-life” in Table 1 represents the time required to decrease the luminance by half at a current density of 33 mA/cm².

In the organic EL device of Example 1 having the heterostructure, the current density driven at 8 V was higher than that in Comparative Examples 1 and 2. This result showed that low-voltage driving could be achieved. The current efficiency and the power efficiency in Example 1 were also superior to those in Comparative Examples 1 and 2. Regarding the luminance half-life, the lifetime of the organic EL device of Example 1 was longer than that of Comparative Examples 1 and 2.

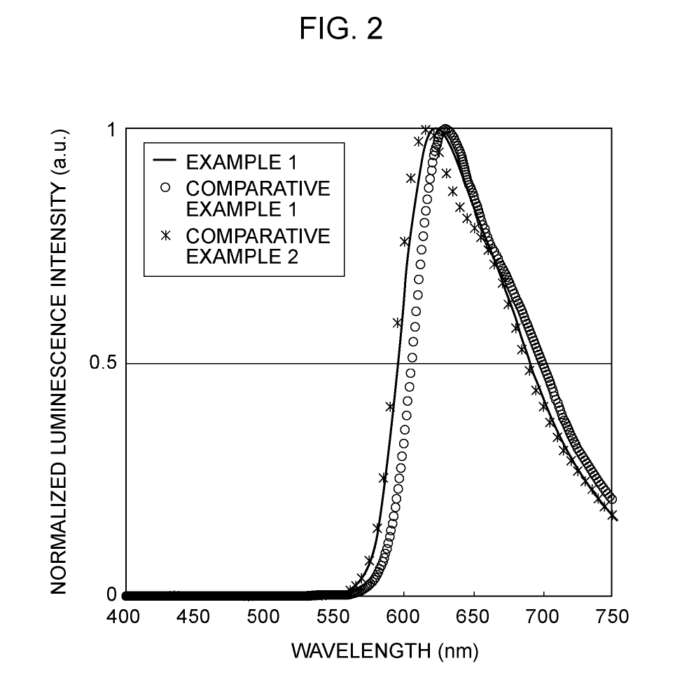

FIG. 2 shows a graph including emission spectra of the devices in Example 1 and Comparative Examples 1 and 2. Ionization potentials of Compounds A and B used in Example 1 and Comparative Examples 1 and 2 were measured by ultraviolet photoelectron spectroscopy (UPS). The electron affinities thereof were determined by converting from the above ionization potentials and measured values of the band gap by optical absorption. The results are shown in Table 2. The term “maximum emission wavelength” in Table 2 represents a value determined by performing photoluminescence (PL) measurement using a dilute toluene solution of the compounds having a concentration of about 10⁻⁵ M. The results are shown in Table 2. In Example 1, the ionization potentials and the electron affinities of the phosphorescent metal complexes in the luminescent layer satisfy the above-described relationships (1) and (2).

TABLE 1

| | | Efficiency | | | | | |
|---|---|---|---|---|---|---|---|
| | Current | at 300 cd/m2 | | Voltage | | | Luminance |
| | density | Current | Power | at | CIE | | half-life |
| | at 8 V | efficiency | efficiency | 300 cd/m2 | chromaticity | | at 33 mA/cm2 |
| | mA/cm2 | cd/A | lm/W | V | x | y | hr |
| Example 1 | 156 | 0.5 | 0.4 | 7.75 | 0.67 | 0.33 | 20 |
| Comparative | 143 | 0.2 | 0.2 | 7.95 | 0.68 | 0.32 | 10 |
| Example 1 | | | | | | | |
| Comparative | 109 | 0.4 | 0.3 | 8.05 | 0.67 | 0.34 | 3 |
| Example 2 | | | | | | | |

TABLE 2
Physical property values of Compounds A and B
(Ionization potential, electron affinity, and maximum
emission wavelength)

| | | |
|---|---|---|
| | | Maximum |
| Ionization | Electron | emission |
| potential | affinity | wavelength |

| | |
|---|---|
| eV | nm |

| | | | |
|---|---|---|---|
| Compound A | 5.24 | 2.97 | 615 |
| Compound B | 5.03 | 2.86 | 626 |

### Example 2

An organic EL device was prepared as in Example 1 except that Compound C was used as the first metal complex constituting the first luminescent sublayer 41, and Compound D was used as the second metal complex constituting the second luminescent sublayer 42.

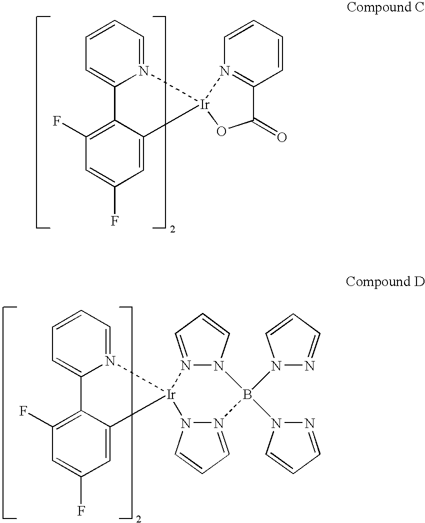

### Comparative Examples 3 and 4

A luminescent layer 4 was composed of a single layer having a thickness of 10 nm. In Comparative Example 3, an organic EL device was prepared as in Example 2 except that the luminescent layer 4 was made of Compound D. In Comparative Example 4, an organic EL device was prepared as in Example 2 except that the luminescent layer 4 was made of Compound C.

Device characteristics of these devices are shown in Table 3. The measurement conditions for the device characteristics were the same as those in Example 1.

TABLE 3

| | | Efficiency | | | | | |
|---|---|---|---|---|---|---|---|
| | Current | at 300 cd/m2 | | Voltage | | | Luminance |
| | density | Current | Power | at | CIE | | half-life |
| | at 8 V | efficiency | efficiency | 300 cd/m2 | chromaticity | | at 33 mA/cm2 |
| | mA/cm2 | cd/A | lm/W | V | x | y | hr |
| Example 2 | 123 | 10.8 | 8.2 | 4.12 | 0.24 | 0.45 | 0.08 |
| Comparative | 103 | 3.4 | 2.5 | 4.36 | 0.26 | 0.44 | 0.03 |
| Example 3 | | | | | | | |
| Comparative | 113 | 6.7 | 5.0 | 4.23 | 0.20 | 0.38 | 0.02 |
| Example 4 | | | | | | | |

In the blue organic EL device of Example 2 having a heterostructure, the current density driven at 8 V was higher than that in Comparative Examples 3 and 4. This result showed that low-voltage driving could be achieved. The current efficiency and the power efficiency in Example 2 were also superior to those in Comparative Examples 3 and 4. Regarding the luminance half-life, the lifetime of the organic EL device of Example 2 was longer than that of Comparative Examples 3 and 4.

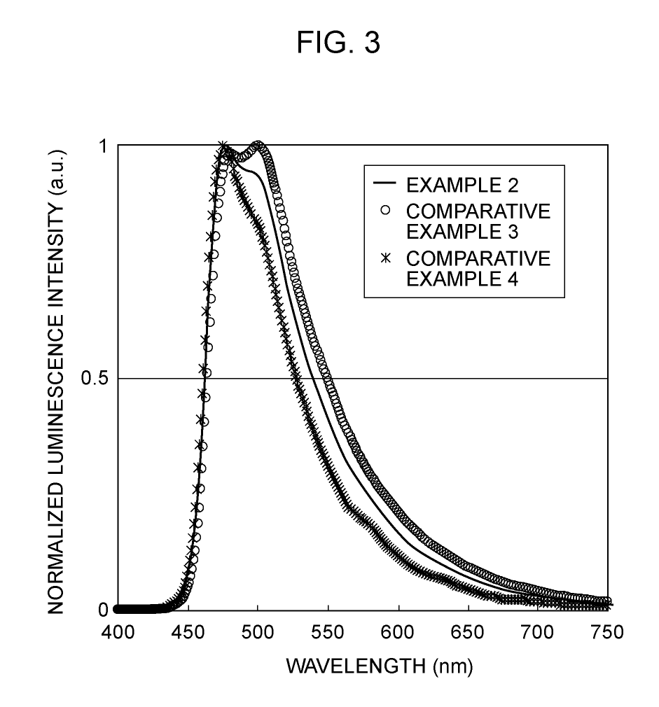

FIG. 3 shows a graph including emission spectra of the devices in Example 2 and Comparative Examples 3 and 4.

Table 4 shows measurement results of ionization potentials and electron affinities of Compounds C and D used in Example 2 and Comparative Examples 3 and 4. The measuring methods were the same as those in Example 1.

TABLE 4
Physical property values of Compounds C and D
(Ionization potential, electron affinity, and maximum
emission wavelength)

| | | |
|---|---|---|
| | | Maximum |
| Ionization | Electron | emission |
| potential | affinity | wavelength |

| | |
|---|---|
| eV | nm |

| | | | |
|---|---|---|---|
| Compound C | 5.8 | 2.9 | 470 |
| Compound D | 6.1 | 3.1 | 458 |

In Example 2, the ionization potentials and the electron affinities of the phosphorescent metal complexes in the luminescent layer satisfy the above-described relationships (1) and (2).

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures and functions.

This application claims the benefit of Japanese Application No. 2006-087017 filed Mar. 28, 2006 and No. 2007-026680 filed Feb. 6, 2007, which are hereby incorporated by reference herein in their entirety.

What is claimed is:

1. An organic electroluminescent device comprising:
an anode;
a cathode;
a luminescent layer disposed between the anode and the cathode; and
a hole-transporting layer disposed between the anode and the cathode,
wherein the luminescent layer includes (a) a first sublayer comprising a first metal complex and (b) a second sublayer comprising a second metal complex which is spaced further from the hole-transporting layer than the first sublayer (a).

2. The organic electroluminescent device according to claim 1, wherein the ionization potential of the first metal complex is represented by Ip(EML1), the electron affinity of the first metal complex is represented by Ea(EML1), the ionization potential of the second metal complex is represented by Ip(EML2), and the electron affinity of the second metal complex is represented by Ea(EML2) and wherein the following two relationships are satisfied:
Ip(EML1)<Ip(EML2) (1)
Ea(EML1)<Ea(EML2) (2).

3. A display apparatus comprising:
a display unit; and
a control circuit for controlling the display of the display unit,
wherein the display unit includes the organic electroluminescent device according to claim 1.
